(19) United States
(12) Patent Application Publication
(10) Pub. No.: US 2014/0214342 A1
(43) Pub. Date: Jul. 31, 2014

(54) VERIFICATION OF TEST PROGRAM STABILITY AND WAFER FABRICATION PROCESS SENSITIVITY

(71) Applicant: NVIDIA CORPORATION, Santa Clara, CA (US)

(72) Inventors: Gunaseelan Ponnuvel, Sunnyvale, CA (US); Keith Michael Katcher, Livermore, CA (US); Tsung-Chi Eddy Yang, San Jose, CA (US); Nerinder Singh, Morgan Hill, CA (US)

(73) Assignee: NVIDIA CORPORATION, Santa Clara, CA (US)

(21) Appl. No.: 13/754,781

(22) Filed: Jan. 30, 2013

(51) Int. Cl. G01R 31/28

(52) U.S. Cl. CPC G01R 31/2855
USPC 702/58

(57) ABSTRACT

A system, method, and computer program product are provided for verifying sensitivity test program stability. A sensitivity test program including a set of tests is run on a plurality of integrated circuit die fabricated on a silicon wafer, where each test in the set of tests specifies a different set of operating parameters for structures within each integrated circuit die. Results of the sensitivity test program are received for each integrated circuit die and the results of the sensitivity test program are stored in shadow bins allocated within a memory, where each shadow bin corresponds to a different test in the set of tests. The results may be used to verify and optimize operating voltage and operating frequency of different tests in the production test program and wafer fabrication process sensitivity.

### FIELD OF THE INVENTION

The present invention relates to integrated circuit test and characterization.

### BACKGROUND

Production test programs are used to test and categorize dies comprising integrated circuits for each fabricated wafer. The operating voltage and operating frequency for a typical production test program are determined based on characteristics that are specific to a particular fabrication process. The characteristics are learned during the fabrication process design characterization/validation using test circuits. A test program may apply a series of tests with an operating voltage supply and the operating clock frequency. The output signals produced by the die for each of the tests are examined, and, if the die fails any test the die is rejected (stop on first fail). The die is tested with each subsequent test in the program and if the die passes all the tests then the die is categorized as a passing die.

The conventional test program that is used to test and categorize dies provides a limited amount of information, merely indicating whether the die passes or fails. Further investigation is needed to determine if the failure is the result of the test program itself or a variation in the wafer fabrication process.

Thus, there is a need for improving the test programs and/or other issues associated with the prior art.

### SUMMARY

A system, method, and computer program product are provided for verifying test program stability. A sensitivity test program including a set of tests is run on a plurality of integrated circuit die fabricated on a silicon wafer, where each test in the set of tests specifies a different set of operating parameters for structures within each integrated circuit die. Results of the sensitivity test program are received for each integrated circuit die and the results of the sensitivity test program are stored in shadow bins allocated within a memory, where each shadow bin corresponds to a different test in the set of tests. The results may be used to verify and optimize operating voltage and operating frequency of different tests in the production test program and wafer fabrication process sensitivity.

### BRIEF DESCRIPTION OF THE DRAWINGS

FIG. 1 illustrates a flowchart of a method for generating test results organized in multiple shadow bins, in accordance with one embodiment;

FIG. 2 illustrates a table specifying the sensitivity test program settings for different shadow bins, in accordance with one embodiment;

FIG. 3 illustrates the integrated circuits within a die that are tested by the sensitivity test program, in accordance with one embodiment;

FIG. 4 illustrates test results for multiple wafers for a set of shadow bins, in accordance with one embodiment;

FIG. 5 illustrates another flowchart of a method for generating and using the test results organized in multiple shadow bins, in accordance with one embodiment;

FIG. 6A illustrates a conceptual diagram illustrating possible applications of the shadow bin data, according to one embodiment;

FIG. 6B illustrates a comparison of logic test path speed indicator utilizing a ring osciallator for the shadow bin, in accordance with one embodiment; and

FIG. 7 illustrates an exemplary system in which the various architecture and/or functionality of the various previous embodiments may be implemented.

### DETAILED DESCRIPTION

Conventional test programs are designed to minimize the time needed to run the test program while providing limited test results allowing for the integrated circuit die to be categorized. The test results provide minimal information, such as whether the die passes the test program. If the die fails a first test in the test program no further testing is performed. The limited test results, i.e. pass/fail, are not generally sufficient to enable differentiation between failures caused by the test program itself or the wafer fabrication process when a die fails the test program. The sensitivity test program may be included within the conventional test program and not affect the categorizing of integrated circuit die resulting from the conventional test program. When the sensitivity test program is incorporated within a mass production conventional test program, a substantially greater amount of voltage and/or frequency sensitivity information is collected in the shadow bins for high volume integrated circuit devices. In contrast with the limited test results produced by the conventional test program, the results may be used to verify and optimize operating voltage and operating frequency of different tests in the production test program and wafer fabrication process sensitivity.

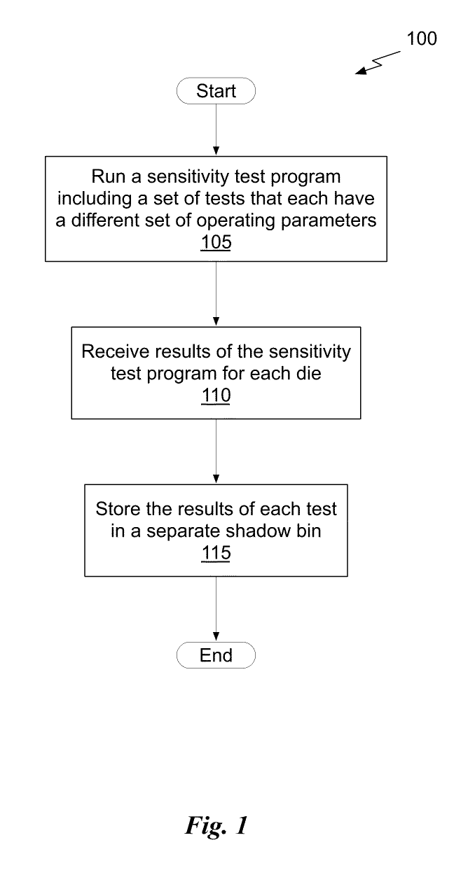

FIG. 1 illustrates a flowchart of a method 100 for generating test results organized in multiple shadow bins, in accordance with one embodiment. At step 105, a sensitivity test program including a set of tests is run on a plurality of integrated circuit die fabricated on a silicon wafer. Each test in the set of tests specifies a different set of operating parameters for structures within each integrated circuit die. At step 110, results of the sensitivity test program are received for each integrated circuit die. The results may be used to verify stability of the sensitivity test program and wafer fabrication process sensitivity. At step 115, the results of the sensitivity test program are stored in shadow bins allocated within a memory, where each shadow bin corresponds to a different test in the set of tests.

More illustrative information will now be set forth regarding various optional architectures and features with which the foregoing framework may or may not be implemented, per the desires of the user. It should be strongly noted that the following information is set forth for illustrative purposes and should not be construed as limiting in any manner. Any of the following features may be optionally incorporated with or without the exclusion of other features described.

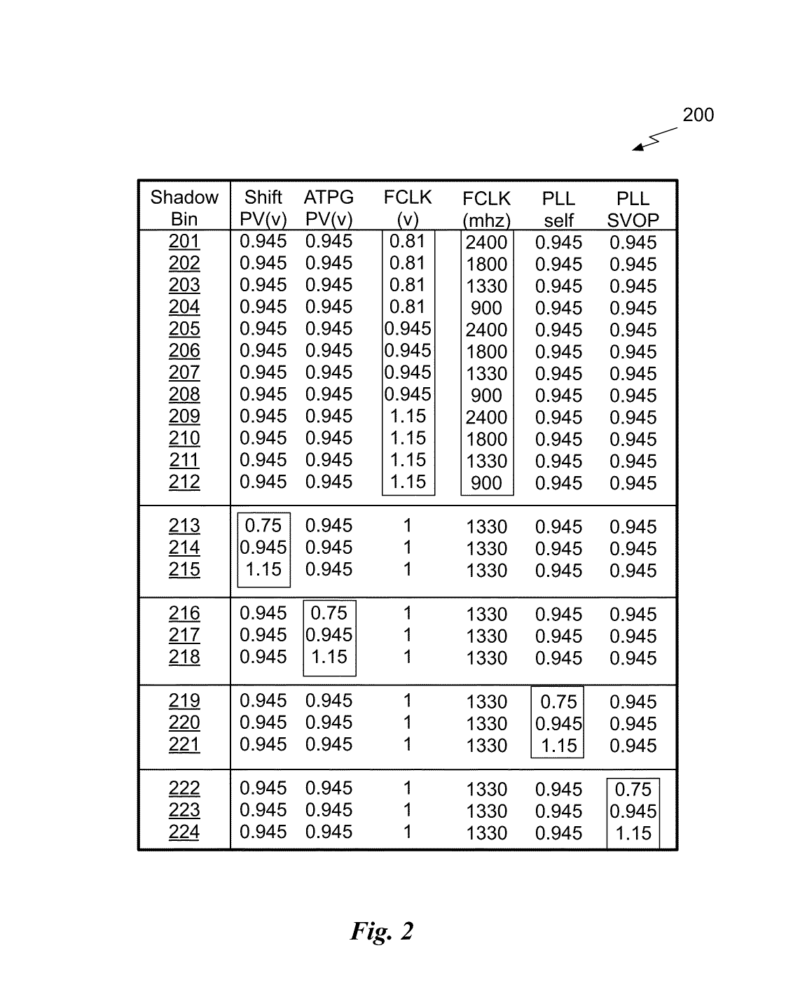

FIG. 2 illustrates a table 200 specifying the operating parameter settings for different shadow bins, in accordance with one embodiment. The first column specifies the shadow bin 201-224. The other columns in the table 200 specify the set of operating parameters for structures within each integrated circuit die for each shadow bin. For example, operating parameters of the Fast Test Mode scan (FTM2CLK) operating voltage and FTM2CLK frequency differ for the shadow bins 201-212. The operating parameters for other structures are constant for the shadow bins 201-212. The voltage operating parameter for the shift chain structure within each integrated circuit die vary for the shadow bins 213, 214, and 215. The voltage operating parameter for the automatic test pattern generation (ATPG) structure within each integrated circuit die varies for the shadow bins 216, 217, and 218. The voltage operating parameter for the Memory Built-in Self Test using phase-locked loop (MBIST PLL) self test structure within each integrated circuit die varies for the shadow bins 219, 220, and 221. The voltage operating parameter for the Memory Built-in Self Test using phase-locked loop (MBIST PLL) structure within each integrated circuit die varies for the shadow bins 222, 223, and 224.

The sensitivity test program that is run on the integrated circuit die of one or more wafers is a sequence of tests configured to use the operating parameter settings of the different shadow bins. The test results that are generated by the integrated circuit die for each combination of operating parameter settings are stored in memory allocated to each shadow bin 201-224. After the sensitivity test program is run on integrated circuit die of one or more wafers, each of the shadow bins in memory stores a pass/fail test result for each integrated circuit die of the one or more wafers. The shadow bins may then be parsed and analyzed to detect any discrepancies between different test results in the same shadow bin or to detect discrepancies between aggregated test results in two different shadow bins that should produce substantially similar aggregated test results. In sum, analysis of the shadow bin data may identify any voltage and/or frequency sensitivity that can be attributed to either test program stability or wafer fabrication process sensitivity.

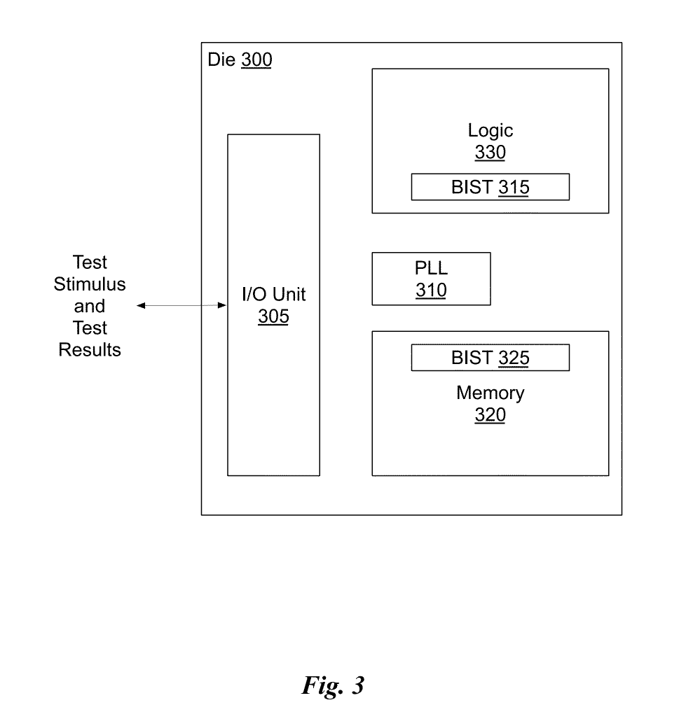

FIG. 3 illustrates the integrated circuits within a die 300 that are tested by the sensitivity test program, in accordance with one embodiment. The test stimulus that encodes the sensitivity test program is input to the die 300 via an I/O unit 305 and the test results that are generated are output via the I/O unit 305. The I/O unit 305 may also include a joint test action group (JTAG) boundary scan chain and/or a shift chain. The die 300 may also include various other structures, such as logic 330, a PLL 310, and a memory 320, e.g., random access memory (RAM). The logic 330 and memory 320 may include built-in self-test (BIST) circuits 315 and 325 that are configured to apply a sequence of test vectors to a structure and report a result indicating whether or not the structure passed the BIST.

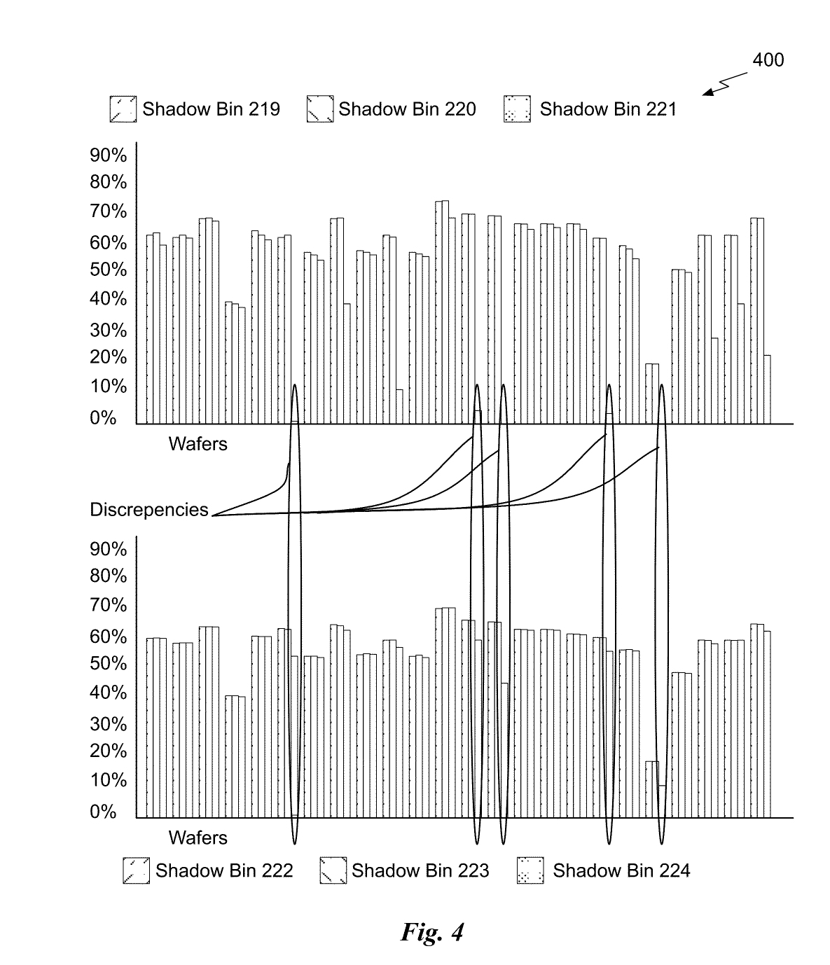

FIG. 4 illustrates test results for the multiple wafers for a set of shadow bins in a graph 400, in accordance with one embodiment. Each set of three bars along the horizontal axis corresponds to the integrated circuit die of a wafer. The vertical axis indicates the percentage yield for the integrated circuit die in different wafer lots. Each bar in a set of three corresponds to one of the shadow bins. In one embodiment a wafer produces 700 integrated circuit die, some of which fail the initial testing for open and short circuits between the supply voltages. As many as 700 integrated circuit die will be tested to generate the shadow bins for each wafer.

The shadow bins 222-224 are configured to vary the supply voltage parameter that is provided to the PLL 310 structure including the BIST circuit 325, so the test result stored in the shadow bins 222-224 is the pass/fail generated by the BIST circuit 325 without the memory 320 structure. The shadow bins 219-221 are configured to vary the supply voltage parameter that is provided to the memory 320 structure with the BIST circuit 325. The yields for shadow bins 219-221 should be substantially the same as shadow bins 222-224 if there is no memory specific voltage sensitivity. As shown in the bar charts, there are some significant discrepancies in the yield results for some of the wafer lots in shadow bins 221 and 224. Therefore, the memory 320 structure is sensitive to a supply voltage level drop below 0.945 volts. A discrepancy in the yield for a first structure of one or more wafers may be caused by the sensitivity test program, by the fabrication process, or by a combination of the sensitivity test program and the fabrication process.

A discrepancy may be the result of a test program stability problem caused by I/O timing sensitivity at the high test speeds, particularly the rise and fall times, high and low signal levels, and the point at which the outputs are sampled. When a sensitivity test program is configured to operate near the margin for one or more operating parameters a test may fail as a result of the sensitivity test program itself. Wafer fabrication process sensitivity results from variations in characteristics of the silicon, such as threshold voltages of transistors, resistivity of metal layers, and the like.

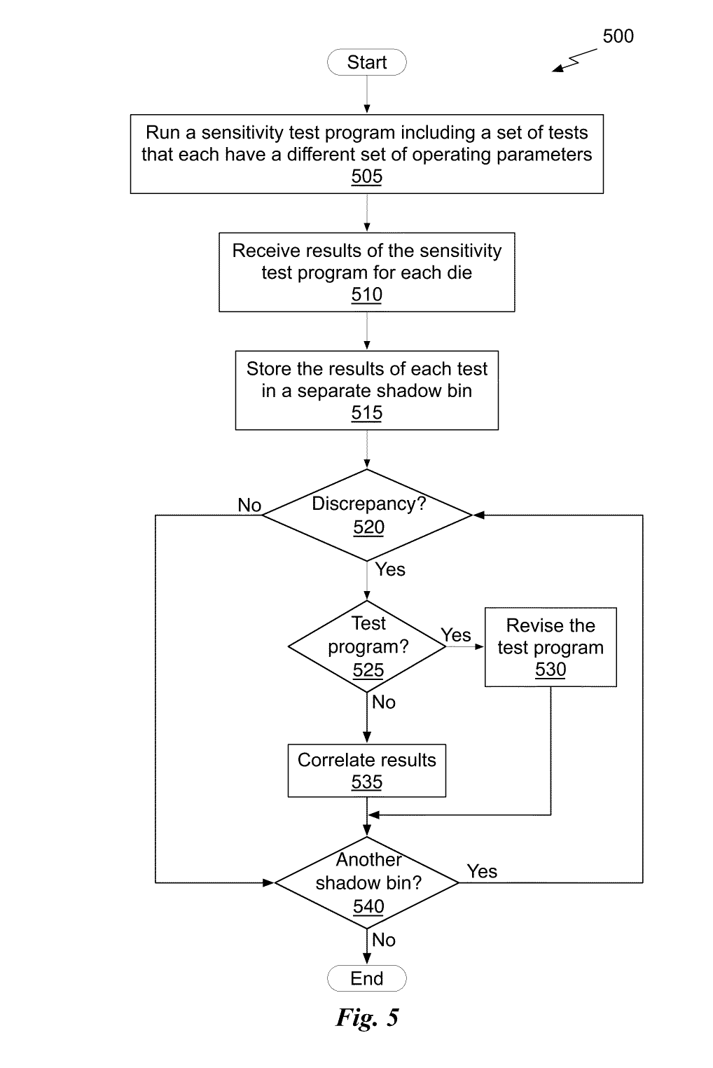

FIG. 5 illustrates another flowchart 500 of a method for generating and using the test results organized in multiple shadow bins, in accordance with one embodiment. Steps 505, 510, and 515 correspond to previously described steps 105, 110, and 115 shown in FIG. 1. One or more of steps 505, 510, 515, and the other steps shown in FIG. 5 may be performed by a test process that is encoded as a program executed by a processor.

At step 520, a shadow bin or a set of related shadow bins are analyzed to identify any discrepancies. Related shadow bins vary a single operating parameter to test a single structure within the integrated circuit die. If, at step 520, the test results in the shadow bin or set of related shadow bins are substantially similar, there is no discrepancy, and the testing process proceeds to step 540 to determine if another shadow bin or set of related shadow bins should be analyzed.

If, at step 520, the test results in the shadow bin or set of related shadow bins are not substantially similar, there is a discrepancy, and the testing process proceeds to step 525. At step 525, the test results are analyzed to determine if the discrepancy for a first structure may be caused by the sensitivity test program, and, if so, at step 530, the production test program is revised to reflect the optimal operating voltage and frequency. Otherwise, at step 535, the test results are correlated with information about the fabrication process to identify the cause of the discrepancy. At step 540, the test process determines if another shadow bin or set of related shadow bins should be analyzed, and, if so, the test process returns to step 520. Otherwise, the test process is complete.

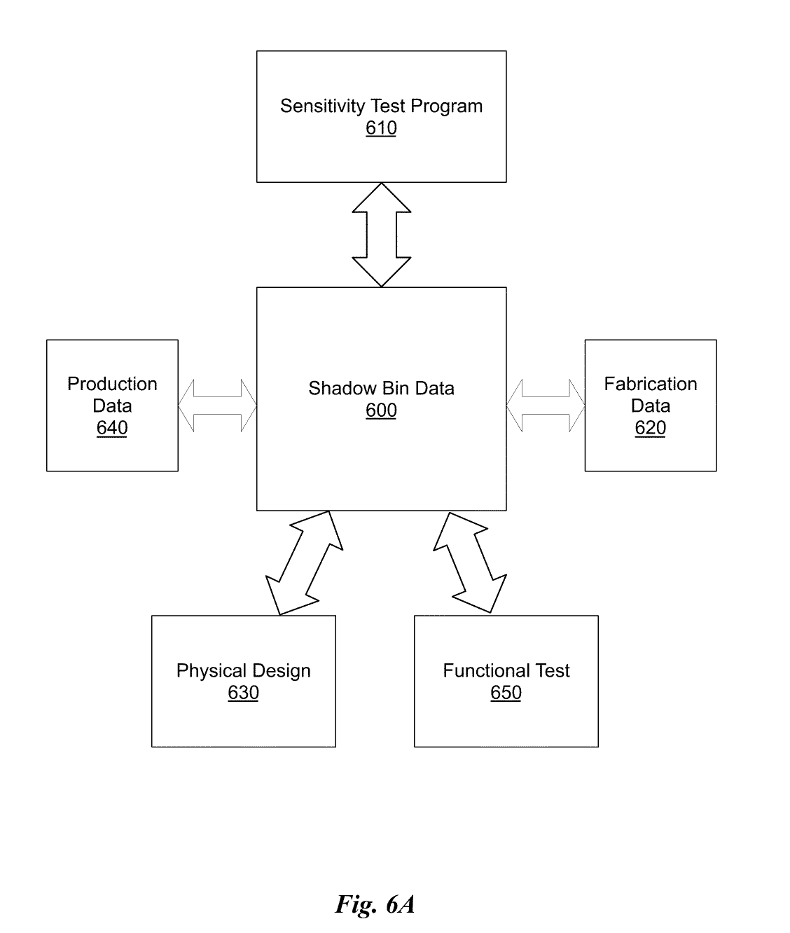

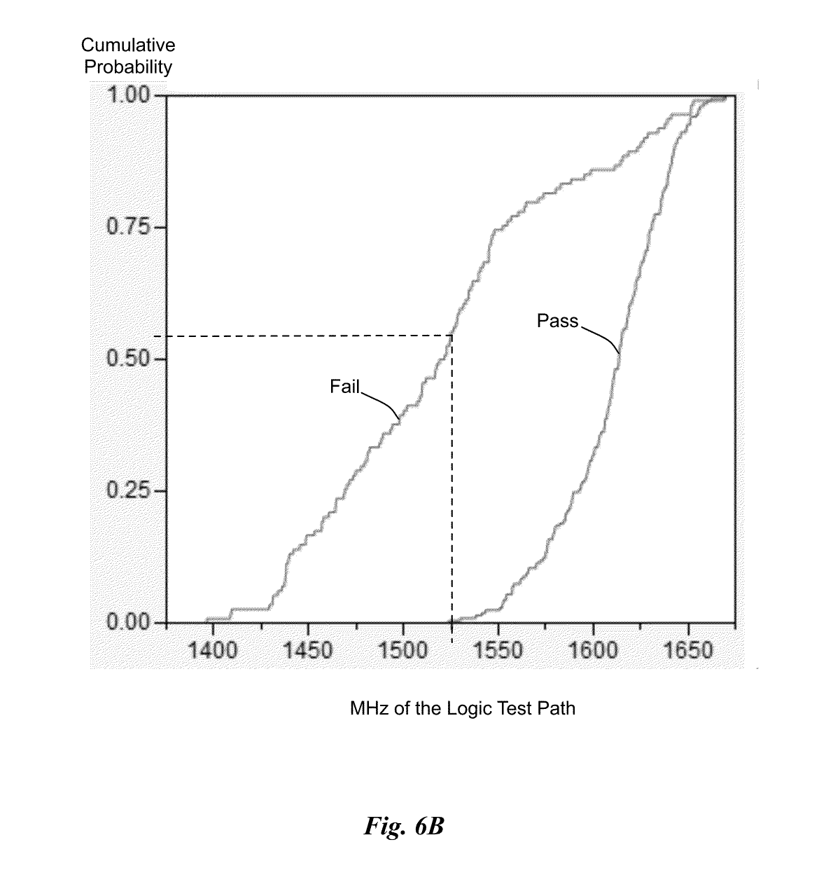

FIG. 6A illustrates a conceptual diagram illustrating possible applications of the shadow bin data 600, according to one embodiment. The shadow bin data 600 is stored in memory, where the test results generated by multiple integrated circuit die of one or more wafers are stored in different shadow bins. The shadow bin data 600 may be analyzed to identify discrepancies resulting from sensitivity test program stability and/or wafer fabrication process sensitivity. The shadow bin data 600 indicating a discrepancy may be provided to different organizations for further analysis and to aid in determining the cause of the discrepancy. The shadow bin data 600 is used to reduce the number of discrepancies caused by sensitivity test program stability by modifying the sensitivity test program 610 based on the shadow bin data 600. The shadow bin data 600 may also be used in combination with the fabrication data 620 to modify the fabrication process to improve integrated circuit die yields. The shadow bin data 600 may be used to generate production data 640 used to perform binning of the integrated circuit die, i.e., categorizing the integrated circuit die based on different operating clock frequencies and/or voltages. The shadow bin data 600 may also be used to modify the physical design 630 of the integrated circuit structures to improve integrated circuit yields. Finally, the shadow bin data 600 may be used in combination with the results of a functional test 650 to debug operation of the integrated circuits.

In one embodiment, a discrepancy is detected for a particular wafer lot for test results in the shadow bins 612 and 613. The shadow bin 612 is a low clock frequency test for an SRAM at 0.7 volts and the shadow bin 613 is a low clock frequency test for the SRAM at 0.8 volts.

| Wafer lot | Shadow bin 612 Yield | Shadow bin 613 Yield |
|---|---|---|
| A | 0.25082 | 0.35005 |
| B | 0.51904 | 0.53754 |
| C | 0.49945 | 0.50382 |
| D | 0.49357 | 0.50292 |

The shadow bin 612 and 613 test results for the wafer lot A are inconsistent with the shadow bin 612 and 613 test results for the wafer lots B, C, and D. In particular, the wafer lot A is sensitive to power supply voltage at the low clock frequency because a 0.1 volt drop in the power supply voltage causes approximately a 10% drop in yield for wafer lot A. The voltage sensitivity for the wafer lot A may be analyzed to identify a cause.

FIG. 6B illustrates an analysis of the voltage sensitivity, in accordance with one embodiment. A cumulative probability plot comparison of a logic test path speed indicator corresponding to a shadow bin 612 illustrates the pass results and the fail results for the dies from a wafer lot A. In one embodiment, the logic test path speed indictor is a ring oscillator. The cumulative probability plot shows that 50% of the dies failing for the shadow bin 612 are measuring the logic test path speed indicator at less than 1525 Mhz. Therefore, a conclusion may be drawn that a logic path is causing SRAM failures at 0.7 volts. This conclusion may be verified by slowing down the operating frequency of the logic path and observing whether or not the SRAM does not fail for the test specified by the shadow bin 612.

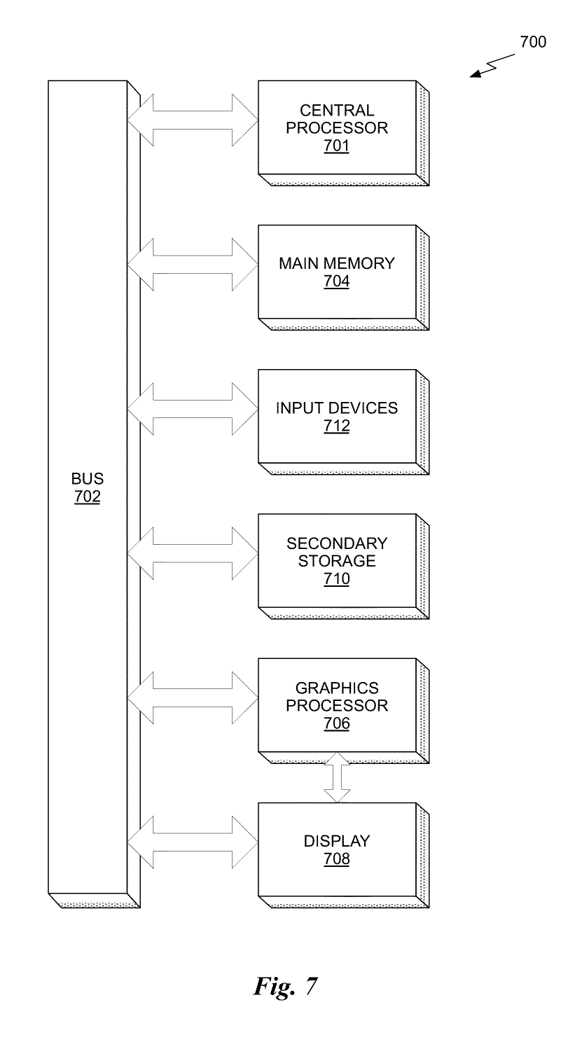

FIG. 7 illustrates an exemplary system 700 in which the various architecture and/or functionality of the various previous embodiments may be implemented. As shown, a system 700 is provided including at least one central processor 701 that is connected to a communication bus 702. The communication bus 702 may be implemented using any suitable protocol, such as PCI (Peripheral Component Interconnect), PCI-Express, AGP (Accelerated Graphics Port), HyperTransport, or any other bus or point-to-point communication protocol(s). The system 700 also includes a main memory 704. Control logic (software) and data are stored in the main memory 704 which may take the form of random access memory (RAM).

The system 700 also includes input devices 712, a graphics processor 706, and a display 708, i.e. a conventional CRT (cathode ray tube), LCD (liquid crystal display), LED (light emitting diode), plasma display or the like. User input may be received from the input devices 712, e.g., keyboard, mouse, touchpad, microphone, and the like. In one embodiment, the graphics processor 706 may include a plurality of shader modules, a rasterization module, etc. Each of the foregoing modules may even be situated on a single semiconductor platform to form a graphics processing unit (GPU).

In the present description, a single semiconductor platform may refer to a sole unitary semiconductor-based integrated circuit or chip. It should be noted that the term single semiconductor platform may also refer to multi-chip modules with increased connectivity which simulate on-chip operation, and make substantial improvements over utilizing a conventional central processing unit (CPU) and bus implementation. Of course, the various modules may also be situated separately or in various combinations of semiconductor platforms per the desires of the user.

The system 700 may also include a secondary storage 710. The secondary storage 710 includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 704 and/or the secondary storage 710. Such computer programs, when executed, enable the system 700 to perform various functions. For example, a sensitivity test program that is run on one or more integrated circuit die may be stored in the main memory 704. The sensitivity test program may be executed by the central processor 701 or the graphics processor 706 and the test results may be stored in different shadow bins in the main memory 704. The main memory 704, the storage 710, and/or any other storage are possible examples of computer-readable media.

In one embodiment, the architecture and/or functionality of the various previous figures may be implemented in the context of the central processor 701, the graphics processor 706, an integrated circuit (not shown) that is capable of at least a portion of the capabilities of both the central processor 701 and the graphics processor 706, a chipset (i.e., a group of integrated circuits designed to work and sold as a unit for performing related functions, etc.), and/or any other integrated circuit for that matter.

Still yet, the architecture and/or functionality of the various previous figures may be implemented in the context of a general computer system, a circuit board system, a game console system dedicated for entertainment purposes, an application-specific system, and/or any other desired system. For example, the system 700 may take the form of a desktop computer, laptop computer, server, workstation, game consoles, embedded system, and/or any other type of logic. Still yet, the system 700 may take the form of various other devices including, but not limited to a personal digital assistant (PDA) device, a mobile phone device, a television, etc.

Further, while not shown, the system 700 may be coupled to a network (e.g., a telecommunications network, local area network (LAN), wireless network, wide area network (WAN) such as the Internet, peer-to-peer network, cable network, or the like) for communication purposes.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A method comprising:
running a sensitivity test program including a set of tests on a plurality of integrated circuit die fabricated on a silicon wafer, wherein each test in the set of tests specifies a different set of operating parameters for structures within each integrated circuit die;
receiving results of the sensitivity test program for each integrated circuit die; and
storing the results of the sensitivity test program in shadow bins allocated within a memory, wherein each shadow bin corresponds to a different test in the set of tests.

2. The method of claim 1, wherein the set of operating parameters comprises at least one of a voltage level and a clock frequency.

3. The method of claim 1, wherein the structures comprises at least one of a random access memory and a phase-locked loop.

4. The method of claim 1, wherein the results of the sensitivity test program indicate a discrepancy for a first structure caused by the sensitivity test program.

5. The method of claim 1, wherein the results of the sensitivity test program indicate a discrepancy for a first structure caused by the fabrication process.

6. The method of claim 1, wherein the plurality of integrated circuit die are packaged prior to running the sensitivity test program.

7. The method of claim 1, wherein the plurality of integrated circuit die are not packaged prior to running the sensitivity test program.

8. The method of claim 1, further comprising parsing the shadow bins to generate yield data for each shadow bin.

9. The method of claim 1, further comprising:
running the sensitivity test program on a plurality of integrated circuit die fabricated on additional silicon wafers to produce additional results; and
storing the additional results in the shadow bins.

10. The method of claim 1, wherein the sensitivity test program is incorporated into a conventional test program.

11. A non-transitory computer-readable storage medium storing instructions that, when executed by a processor, cause the processor to perform steps comprising:
running a sensitivity test program including a set of tests on a plurality of integrated circuit die fabricated on a silicon wafer, wherein each test in the set of tests specifies a different set of operating parameters for structures within each integrated circuit die;
receiving results of the sensitivity test program for each integrated circuit die; and
storing the results of the sensitivity test program in shadow bins allocated within a memory, wherein each shadow bin corresponds to a different test in the set of tests.

12. The non-transitory computer-readable storage medium of claim 11, wherein the set of operating parameters comprises at least one of a voltage level and a clock frequency.

13. The non-transitory computer-readable storage medium of claim 11, wherein the structures comprises at least one of a random access memory and a phase-locked loop.

14. The non-transitory computer-readable storage medium of claim 11, wherein the results of the sensitivity test program indicate a discrepancy for a first structure caused by the sensitivity test program.

15. The non-transitory computer-readable storage medium of claim 11, wherein the results of the sensitivity test program indicate a discrepancy for a first structure caused by the fabrication process.

16. The non-transitory computer-readable storage medium of claim 11, further comprising parsing the shadow bins to generate yield data for each shadow bin.

17. A system comprising:
a memory; and
a processor that is coupled to the memory and configured to:
run a sensitivity test program including a set of tests on a plurality of integrated circuit die fabricated on a silicon wafer, wherein each test in the set of tests specifies a different set of operating parameters for structures within each integrated circuit die;
receive results of the sensitivity test program for each integrated circuit die; and
store the results of the sensitivity test program in shadow bins allocated within the memory, wherein each shadow bin corresponds to a different test in the set of tests.

18. The system of claim 17, wherein the set of operating parameters comprises at least one of a voltage level and a clock frequency.

19. The system of claim 17, wherein the results of the sensitivity test program indicate a discrepancy for a first structure caused by the sensitivity test program.

20. The system of claim 17, wherein the results of the sensitivity test program indicate a discrepancy for a first structure caused by the fabrication process.
